(19) United States
(12) Patent Application Publication
(10) Pub. No.: US 2011/0253204 A1
(43) Pub. Date: Oct. 20, 2011

(54) Solar Cell

(75) Inventors: Wataru Koshibae, Wako-shi (JP); Masao Nakamura, Wako-shi (JP); Masashi Kawasaki, Wako-shi (JP); Naoto Nagaosa, Wako-shi (JP); Yasujiro Taguchi, Wako-shi (JP); Yoshinori Tokura, Wako-shi (JP); Nobuo Furukawa, Wako-shi (JP)

(73) Assignee: Riken

(21) Appl. No.: 13/081,878

(22) Filed: Apr. 7, 2011

(30) Foreign Application Priority Data
Apr. 15, 2010 (JP) 2010-094361

(51) Int. Cl. H01L 31/02

(52) U.S. Cl. 136/255

(57) ABSTRACT

A solar cell 1 has a p-n junction structure between a first solid material layer 3 comprising an insulator or a semiconductor and a second solid material layer 5 comprising an insulator or a semiconductor of a type different from the type of the first solid material layer 3, in which structure a Mott insulator or a Mott semiconductor is used as a solid material of at least one of the layers.

### BACKGROUND OF THE INVENTION

1. Field of the Invention

The present invention relates to a solar cell, and particularly to a solar cell using a phenomenon that is unique to a strongly correlated electron system, the phenomenon being discovered in a transition process of a Mott insulator or a Mott semiconductor to a metal phase upon light irradiation is applied.

2. Description of the Related Art

Silicon element, gallium-arsenic compound semiconductors, and the like are presently used as a material exhibiting solar cell functions. The principle of photovoltaic energy conversion in these materials involves the use of single-electron excitation induced by photons as shown in FIG. 8. A solar cell utilizing the single-electron excitation has such a limitation that one electron is excited by one photons. Carriers (electrons and holes) receiving an energy exceeding the band gap undergo only heat dissipation, until the carriers reach the band edge. Accordingly, in principle, there is a limitation on the photovoltaic conversion efficiency.

Materials in which the single-electron excitation occurs are solid materials so-called band semiconductors which accord with a single-electron band theory. Typical materials for such band semiconductors are silicon semiconductors, gallium arsenic, and the like. Currently manufactured or developed solar cells are based on such materials.

Meanwhile, there is a series of solid materials in which electrons show different behavior from those of the above band semiconductors. These solid materials are called Mott insulators or Mott semiconductors. The Mott insulators or Mott semiconductors refer to the following solid materials. Specifically, when the number of electrons at each lattice point in a crystal structure is an odd number, the solid materials are expected to have metal-like electrical properties on the basis of the Pauli exclusion principle, but exhibit insulating properties because of localization of electrons (generation of an energy gap) which is caused when strong Coulomb repulsion acting between electrons exceeds the ease of electron movement from one lattice point to another (electron conduction energy). The use of Mott insulators or Mott semiconductors having the conduction mechanism as solar cell materials has not been considered so far.

The above-described solid materials are not ordinarily called as Mott semiconductors but Mott insulators. However, as various applications, including solar cells, of Mott insulators are developed in future, Mott insulators having a low electrical resistance may be called as Mott semiconductors. Hence, the term “Mott semiconductor” is also used in this context.

Among Mott insulators or Mott semiconductors, transition metal oxides have been intensively studied in the course of searching for superconducting materials. The inventors of the present application have found that especially manganese oxide-based materials based on LnMnO₃ (Ln: rare-earth metal element) undergo a metal-insulator phase transition upon receiving an external perturbation such as magnetic field and light. Based on the knowledge, the present inventors have proposed a light switching element utilizing photo-induced insulator-metal transition occurring upon light irradiation (see, for example, Japanese Patent Application Publication No. H10-261291).

The present inventors have invented a magneto resistive element made of a perovskite oxide material containing manganese (see, for example, Japanese Patent Application Publication No. 2001-257396). In the magneto resistive element, metal-insulator transition of a Mott insulator or a Mott semiconductor is employed as the principle of a magneto resistive effect. Application of such a phase transition phenomenon of a Mott insulator or a Mott semiconductor has been tried in various application fields of electronics such as light switching elements, magnetometric sensors and memory devices.

### SUMMARY OF THE INVENTION

However, there are no detailed theoretical studies on the electron behavior during a metal-insulator phase transition induced by light irradiation in a Mott insulator or a Mott semiconductor. In addition, there have been no attempts to apply such electron behavior to a solar cell.

In order to achieve the above-described object, a solar cell according to the present invention is provided, which comprises solid material layers containing insulators or semiconductors of different types that are joined, and in which any one of the solid material layers contains a Mott insulator or a Mott semiconductor.

The solar cell of the present invention enables to dramatically improve the conversion efficiency per photon absorbed, in the following manner. Specifically, in the process of carriers having energy exceeding the Mott gap being relaxed to the band edge of the corresponding upper or lower energy band, carrier relaxation process undergoes carrier excitation as well as heat dissipation. By extracting these carriers through electrodes, the conversion efficiency can be improved.

### BRIEF DESCRIPTION OF THE DRAWINGS

FIG. 1 is a schematic cross-sectional view illustrating one embodiment of a solar cell according to the present invention.

FIG. 2 is a graph illustrating an energy barrier in the insulator-metal phase transition.

FIG. 3 is a graph showing the number of electrons (per spin) occupying an upper energy band in the phase transition process of Mott insulator to metal after carrier excitation by irradiation of light, and illustrating the change in energy with time during the phase transition process.

FIGS. 4 (a) to (c) are schematic diagrams illustrating change in magnetic structure with time during an insulator-metal phase transition process occurring after a carrier excitation at time 0 by irradiation of a Mott insulator with light {(a): time 1600, (b): time 7830, and (c): time 15000}.

FIG. 5 is a schematic diagram illustrating a carrier excitation/relaxation process of the solar cell according to the present invention upon light irradiation.

FIG. 6 is a schematic cross-sectional view illustrating another embodiment of a solar cell according to the present invention.

FIG. 7 is a graph illustrating photovoltaic characteristics of a Mott insulator fabricated by using basic production steps for the solar cell according to the present invention.

FIG. 8 is a schematic diagram illustrating a carrier excitation/relaxation process upon light irradiation in the conventional p-n junction band semiconductor.

### DETAILED DESCRIPTION OF CERTAIN EMBODIMENTS

Hereinafter, the present invention will be described in detail with reference to the drawings. The same components are denoted by the same numerals. Note that the present invention is not limited to embodiments to be described below. Embodiments of the present invention will be described below with reference to the drawings. However, the present invention is not limited to the following description. One skilled in the art can easily understand that the embodiments and details can be modified in various manners without departing from the gist of the present invention and from the scope of the present invention. Accordingly, one should understand that the technical scopes of the present invention are not limited to the following description of the embodiments. In the configurations of the present invention to be described below, reference numerals denoting the same components are used commonly among different drawings.

### Embodiment 1

Hereinafter, an embodiment of the present invention will be described in detail on the basis of the drawings.

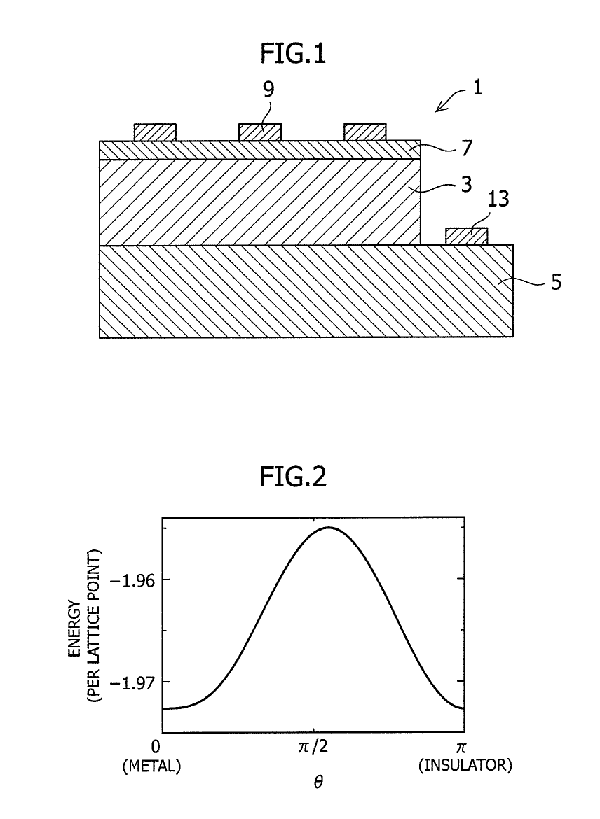

In a mode shown in FIG. 1, a solar cell 1 comprises a first electrode 7 formed on a sunlight-receiving surface; a first solid material layer 3 formed of a p-type or n-type insulator or a p-type or n-type semiconductor under the first electrode 7; a second solid material layer 5 is formed of an insulator or semiconductor of a type different from that of the first solid material layer 3 under the first solid material layer 3; the two layers 3 and 5 form a p-n junction; and the second solid material layer 5 also has a function of an electrode. Here, at least one of the first and second solid materials is a Mott insulator or a Mott semiconductor.

When such a solar cell is employed, the state of electrons excited by sunlight is totally different from that of excited electrons in conventional cases. This is because almost all Mott insulators or Mott semiconductors are accompanied by ordered magnetic states. Moreover, excited electron spins interact closely with an ordered magnetic state (magnetic moment). As a result, the magnetic structure in the ground state is strongly influenced. Consequently, electrons in an excited state are strongly influenced by the changed magnetic structure.

The double-exchange model shown in the following formula well describes this feature:

$$H = - i {\sum }_{〈 ij 〉 , σ} ( {c}_{i σ}^{†} {c}_{j σ} + h . c . ) - {J}_{H} {\sum }_{i} ( {\overline{σ}}_{{σσ}^{′}} {c}_{i σ}^{†} {c}_{i {σ}^{′}} ) \cdot {\vec{S}}_{i} + {H}_{S} \qquad ( 1 )$$

where t represents the kinetic energy, J_{H} represents the exchange energy, σ and σ′ represent electron spins, i and j represent the coordinates of a lattice point, and <ij> appearing in the sum represents a set of closest lattice points. The operator

c_{iσ}^{↑} (c_{jσ})

represents a creation (annihilation) operator of an electron with a spin a at a lattice point i(j).

\vec{σ}

in the second term represents a Pauli matrix, and

\vec{S}ᵢ

represents a localized spin representing the magnetic moment at a lattice point i. The first term in the formula (1) represents the Hamiltonian for electrons in motion, and the second term represents the interaction between electron spins in motion and localized spins. The third term H_{S} means the Hamiltonian of localized spins, into which the anisotropy in the magnetic interaction of the target substance can be incorporated.

When H_{S} contained in the formula (1) takes the following form, an antiferromagnetic insulating state unstable due to a possible first-order transition to a ferromagnetic metallic state can be taken as the ground state:

$${H}_{S} = + J {\sum }_{〈 ij 〉} {\vec{S}}_{i} \cdot {\vec{S}}_{j} + {J}_{N} {\sum }_{〈 ij 〉} {( {\vec{S}}_{i} \cdot {\vec{S}}_{j} )}^{2} \qquad ( 2 )$$

FIG. 2 shows the results of a numeric value simulation of the lowest energy state of the formula (2). Here, it is assumed that a 8×8 two-dimensional square lattice is employed, and an electron system where a half of electron orbitals are occupied by electrons, and parameters are selected as follows: t=1, S=1, SJ_{H}=1.0, J=−0.086, and J_{N}=−0.086. FIG. 2 shows the lowest energy in such a case, with the angle θ formed by localized spins in sub lattices being shown on the horizontal axis.

As can be seen from this graph, an antiferromagnetic (insulator) state at θ=π is separated from the ferromagnetic (metal) state at θ=0 by an energy barrier having a height of about 0.02.

The electron system in the antiferromagnetic (insulator) state was excited, and the relaxation process thereof was quantitatively investigated in detail by conducting a numerical simulation. As a result, it has been found that a ferromagnetic metallic state appears as the final state. Here, the effect of energy dissipation of the entire system is incorporated into the Gilbert damping term of motion of localized spins. Specifically, when the effective magnetic field acting on a localized spin at a lattice point i is denoted by

\vec{h}ᵢ,

the equation of motion of

\vec{S}ᵢ

is represented by the following formula:

$$\frac{d}{d t} {\vec{S}}_{i} = - {\vec{h}}_{i} \times {\vec{S}}_{i} - α {\vec{S}}_{i} \times \frac{d}{d t} {\vec{S}}_{i} \qquad ( 3 )$$

The term containing α is the Gilbert damping term, and a is a damping constant. On the basis of the Hellmann-Feynman theorem, the effective magnetic field

\vec{h}ᵢ

and the Hamiltonian have the following relationship:

$${\vec{h}}_{i} = \frac{\partial H}{\partial {\vec{S}}_{i}} \qquad ( 4 )$$

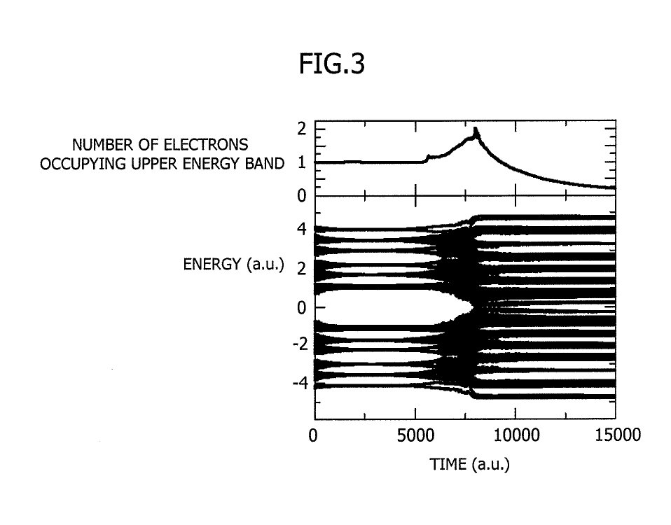

FIG. 3 shows simulation experiment results at α=0.01. The lower panel shows how the energy level of an electron develops with time. As the initial state, a state obtained by exciting an electron in the antiferromagnetic insulator state was employed. Specifically, at the initial stage, there is an energy gap of about two in an arbitrary unit centered at zero representing the Fermi level, so that two separated energy bands are formed. In the ground state, the lower energy band is filled with electrons, and the upper energy band is empty. As the initial state of the relaxation process, employed was a state obtained by exciting an electron in the lowest energy level in the lower energy band to the highest energy level in the upper energy band. Specifically, the upper energy band contains one electron at the initial stage of the relaxation process. The upper panel in FIG. 3 shows the time dependence of the number of electrons per up or down spin contained in the upper energy band.

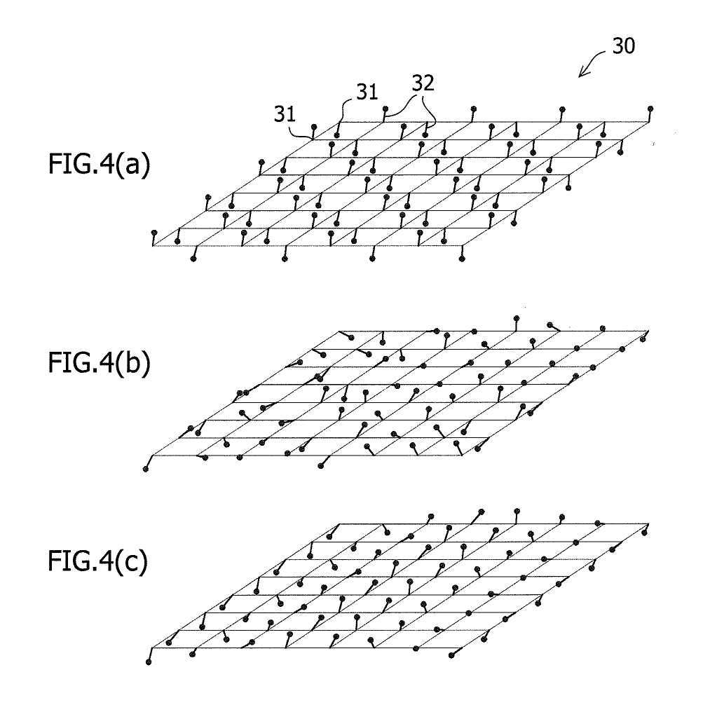

From the initial stage to around the time 5000 in the relaxation process, the system takes an antiferromagnetic structure, and has an energy gap to which the antiferromagnetic structure is reflected. In addition, the number of electrons contained in the upper energy band is substantially constant. Between the time 5000 and the time 8000, the magnetic structure is reconstructed, and the energy gap characteristic of an antiferromagnetic structure is gradually closed. Moreover, it can be seen that there exists a period of time where the number of electrons contained in the upper energy band becomes greater than the initial value. This indicates the occurrence of a multiple-excitation phenomenon, which cannot occur in a single-electron band. Eventually, the number of electrons contained in the upper energy band starts to decrease, and the system shows a time development leading to the final state of a ferromagnetic metal phase. In the magnetic structure at around the time 15000, a long-period spiral magnetism appears which is locally substantially ferromagnetic as will be described below. Then, the magnetic structure transits toward a structure having metallic energy levels in the final state. The excited electrons contained in the upper energy band transit to the lower energy band, and the value becomes sufficiently small, as the state becomes closer to the final state. The sequential process strongly reflects the magnetic structure formed by localized spins. FIG. 4 shows the relaxation process.

In the initial state immediately after the light excitation, localized spins 32 in lattice points 31 are in an antiferromagnetic state as shown in Part (a) of FIG. 4. Here, a match-like shape 32 at each lattice point represents a spin localized at the lattice point, and the direction of the match-like shape 32 indicates the direction of the spin. As time goes on, the magnetic structure 30 in the initial state considerably changes its shape, while being accompanied with active dynamic behaviors. Part (b) of FIG. 4 shows a snap shot taken during this period. After the active time development of the magnetic structure, the magnetic structure converges toward the final state as shown in Part (c) of FIG. 4. In the cases of actual substances, the kinetic energy (t) is at most about 1 eV. With t being used as a unit, the magnitudes of other interactions are selected so as to be realistic values. A time of several thousands here corresponds to several picoseconds in the relaxation process of an actual substance.

What is characteristic in this relaxation process is the dynamic relaxation between the time 5000 to the time 10000. This period involves a dynamic relaxation process showing the transition from an antiferromagnetic phase to a ferromagnetic phase. To further promote the phase transition and relaxation, a larger number of electron-hole pairs are generated in the electron system than those generated at the initial stage. In comparison with conventional electronic materials, the emergence of the generation process of multiple “electron-hole” pairs along with the relaxation is a marked characteristic of a system including strong Coulomb interaction acting between electrons. The present inventors first demonstrated an example of multiple-carrier generation in a Mott insulator or a Mott semiconductor.

The electron state of conventional electron materials is well understood by an electronic theory based on the one electron approximation. In the electron excitation and the relaxation process thereof in an insulator, a part of the excitation energy of electron-hole pairs exceeding the magnitude of the energy gap is simply dissipated. When the electrons reach the lower edge of the conduction band, and the holes reach the upper edge of the valence band, pair annihilation thereof occurs. In contrast, in a system including a strong Coulomb interaction, a part of the excitation energy of electron-hole pairs exceeding the magnitude of the energy gap is not only dissipated, but also causes a dynamic relaxation process, which consequently leads to the generation of further multiple “electron-hole” pairs as shown in FIG. 5.

The model used in the present invention extremely well describes the electron states around transition metal compounds. For example, this model gives quantitatively good results in the cases of electronic properties of manganese oxides exhibiting a giant magneto resistive effect. Properties of individual actual substances can be reproduced by adjusting the parameters contained in the formula. A theoretical example of the electron excitation and the relaxation process thereof obtained by the present invention directly gives a leading principle for development of a highly-efficient solar cell based on a novel power generation mechanism using a Mott insulator or a Mott semiconductor.

The solar cell according to the present invention comprises a Mott insulator or a Mott semiconductor. The Mott insulator or the Mott semiconductor may be an inorganic compound or an organic compound. Typical Mott insulators are inorganic compounds containing a 3d transition metal element, a 4d transition metal element, or a 5d transition metal element, or organic compounds. The Mott gap attributable to the Coulomb repulsion of the Mott insulator is desirably 1 eV or less in order to effectively utilize the energy region of sunlight.

The Mott insulator or the Mott semiconductor of the inorganic compound is not particularly limited as long as the Mott insulator or the Mott semiconductor has a Mott gap. Accordingly, the Mott insulator or the Mott semiconductor is an insulator formed of one or more transition metal elements selected from the group consisting of titanium, vanadium, chromium, manganese, iron, cobalt, nickel, copper, zinc, molybdenum, ruthenium, rhodium, cadmium, indium, tin, rhenium, osmium, iridium, and platinum. In addition, the Mott insulator or the Mott semiconductor may be any one of the following general formulae (1) to (8):

LnₓA₁₋ₓBO₃ (1)

LnAB₂O₆ (2)

Ln₁₋ₓA₁₊ₓBO₄ (3)

Ln₂₋₂ₓA₁₊₂ₓB₂O₇ (4)

Ln₂₋ₓAₓBO₄ (5)

A₂BO₃ (6)

A₂BO₄ (7)

A₂BO₂Cl₂ (8)
(where Ln represents one or more rare-earth elements selected from the group consisting of lanthanum, cerium, praseodymium, neodymium, samarium, erbium, thulium, ytterbium, and lutetium; A represents one or more alkaline earth metal elements selected from the group consisting of beryllium, magnesium, calcium, strontium, and barium; B represents one or more transition metal elements selected from the group consisting of titanium, vanadium, chromium, manganese, iron, cobalt, nickel, copper, zinc, niobium, molybdenum, ruthenium, rhodium, cadmium, indium, tin, tantalum, tungsten, rhenium, osmium, iridium, and platinum; O represents oxygen element, Cl represents chlorine element; and x satisfies 0≦x≦1).

Among these, a manganese oxide [LnₓA₁₋ₓMnO₃] having a perovskite-type crystal structure is preferably used. Here, a preferred upper limit of x may vary depending on the kind of the transition metal element used, and the like. Any lattice substitution (filling control) by ions having a different valence is allowed, as long as the manganese oxide has a Mott gap.

The Mott insulator or the Mott semiconductor which is the aforementioned inorganic compound may be any one of vanadium oxide, niobium oxide, tantalum oxide, chromium oxide, molybdenum oxide, tungsten oxide, and rhenium oxide.

The Mott insulator or Mott semiconductor is not limited to inorganic compounds. This is because organic compounds are generally Mott insulators or Mott semiconductors. The organic compounds are any of an aromatic amine compound, a carbazole derivative, an aromatic hydrocarbon, a polymer compound, and a charge transfer complex. The charge transfer complex may be any one of a quasi-one-dimensional halogen-bridged metal complex [MX complex], a quasi-one-dimensional halogen-bridged multinuclear metal complex [MMX complex], and an aromatic hydrocarbon which is a quasi-one-dimensional charge transfer complex including tetrathiafulvalene [TTF] and chloranil [CA]. The quasi-one-dimensional halogen-bridged metal complex is a chain material where a transition metal (M) and a halogen (X) are alternately arranged. Examples of the quasi-one-dimensional halogen-bridged metal complex and the quasi-one-dimensional halogen-bridged multinuclear metal complex include compounds represented by [Ni_{1-y}Pd_{y}(chxn)₂X1]X2₂ [where y represents a number not less than 0 but not more than 1, X1 and X2 are the same or different, and represent a halogen selected from F, Cl, Br, and I, and chxn represents cyclohexanediamine]; Pt₂(EtCS₂)₄I; Pt₂(n-BuCS₂)₄I; and the like.

In the solar cell according to the present invention, solid material layers containing different types of insulators or semiconductors are joined, and at least one of the solid material layers contains a Mott insulator or a Mott semiconductor.

In this description, “an insulator or a semiconductor” includes not only Mott insulators and Mott semiconductors, but also conventionally known band semiconductors in which electrons are excited by photons on a one-to-one basis.

Accordingly, examples of the junction structure between the insulators or the semiconductors of different types include combinations of an n-type Mott insulator and a p-type band semiconductor; an n-type Mott insulator and a p-type Mott insulator; a p-type Mott insulator and an n-type band semiconductor; a p-type Mott insulator and an n-type Mott insulator; and other combinations.

The n-type Mott insulator is not particularly limited, and examples thereof include SrMnO₃, CaMnO₃, Ln₂CuO₄ (Ln=a rare-earth element such as lanthanum, cerium, or praseodymium), tungsten oxide (WO₃), and the like.

Examples of the p-type Mott insulator include oxygen-excess or Ln-deficient LnMnO₃, Ln₁₋ₓAₓMnO₃ (A represents a divalent alkaline earth metal element), La₂CuO₄, vanadium oxide (VO₂), chromium oxide (Cr₂O₃), and the like.

Examples of the n-type band semiconductor include Si:As, Si:Sb, SrTiO₃:Nb, TiO₂, ZnO, ZnO:Al, ZnO:I, ZnS, ZnSe, CdS, CdSe, and the like.

Examples of the p-type band semiconductor include Cu—In—Se systems such as Si;B, Si;Al, ZnTe, Cu₂O, Cu₂S, Cu₂Te, CuO, and Cu(In, Ga)₃Se₅, InP, and the like.

Incidentally, GaAs and CdTe can be any of the n-type and p-type band semiconductors.

The transition metal elements used in the insulators or semiconductors forming the p-n junction may be different or the same.

The solar cell of the present invention can be obtained by forming on a substrate a multi-layered structure at least one layer of which comprises the Mott insulator or the Mott semiconductor. The substrate may be the second solid material layer 5 itself as shown in FIG. 1, or may be separately provided to support the second solid material layer 5.

In a method of forming the multi-layered structure, for example, the first solid material layer 3 is formed on the second solid material layer 5 serving also as the substrate for the solar cell as shown in FIG. 1. Subsequently, the first electrode 7 of a thin film having a desired thickness is formed on the first solid material layer 3. On the first electrode 7, first auxiliary electrodes 9 are formed.

A method of forming the film for each layer is not particularly limited, and, for example, the pulsed laser deposition method (PLD) method, the laser ablation method, the molecular beam epitaxy method (MBE method), the sputtering method, the plasma CVD method, the metal organic chemical vapor deposition method (MOCVD method), the spin coating method, the inkjet method, or the like may be employed as the method.

When the first solid material layer comprises a Mott insulator or a Mott semiconductor, the thickness of the layer is generally 4 A (A represents ångström) to 10000 A, from the viewpoint of the balance between the absorption coefficient of the Mott insulator or the Mott semiconductor and the effective thickness thereof defined as the sum of the depletion layer width and the diffusion length. For a case where sunlight, particularly light with wavelengths in the visible region, is transmitted and reaches the second solid material layer, the thickness can be about several A to 100 A, for example.

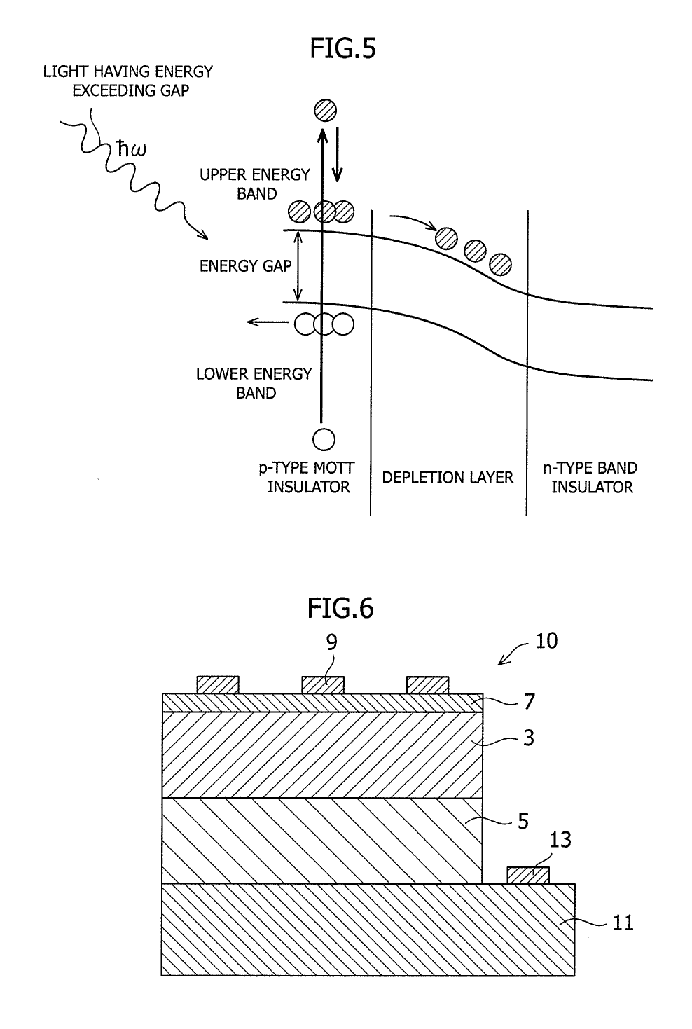

In a second mode shown in FIG. 6, a solar cell 10 comprises a layer 3 containing a Mott insulator or a Mott semiconductor and a layer 5 containing a band semiconductor, and the layers 3 and 5 are joined to each other. In addition, the layer 5 containing the band semiconductor includes a second electrode 11 which also serves as a lower substrate. A material of the band semiconductor substrate is selected as appropriate with the compatibility with the Mott insulator or the Mott semiconductor taken into consideration. For example, a Nb-doped SrTiO₃ substrate or the like can be employed as the band semiconductor substrate. A material of the second electrode 11 is selected as appropriate with the compatibility with the layer 5 containing the band semiconductor taken into consideration. For example, gold, silver, platinum, titanium, aluminum, copper, or tungsten can be employed as the material. A material of a second auxiliary electrode 13 is selected as appropriate with the compatibility with the second electrode 11 taken into consideration. For example, gold, silver, platinum, titanium, aluminum, copper, or tungsten can be employed as the material.

The solar cell of the present invention may include two or more of the p-n junction structures each formed of the first solid material layer and the second solid material layer. For example, the solar cell may be such that two or more of the p-n junction structures are connected in series.

Moreover, the solar cell may be provided with an irregular surface structure for the purpose of enhancing the effect of collecting light on the light-receiving surface.

Specific examples of the layer structure of the solar cell of the present invention include, for example, Au/La₂CuO₄/SrTiO₃:Nb, Au/Pr_{0.7}Ca_{0.3}MnO₃/SrTiO₃:Nb, Au/LaMnO₃/SrTiO₃:Nb, and the like.

### Embodiment 2

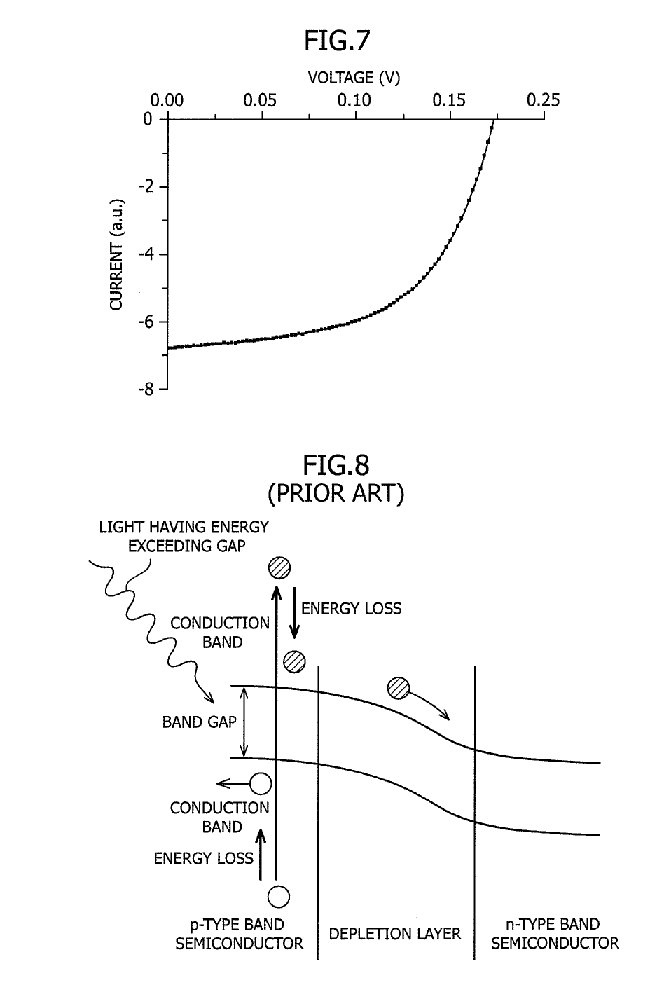

On the basis of the above-described simulation example, a solar cell as shown in FIG. 1 was fabricated in which a p-n junction was formed of a p-type Mott insulator and an n-type band semiconductor. First, an n-type band semiconductor, Nb;SrTiO₃ crystal, was used as the substrate 5, which was designed to serve also as a lower electrode. On the substrate 5, a p-type Mott insulator LaMnO₃, was formed by the laser ablation method in a thickness of 300 A. The film was formed under the conditions of 850° C. and 1 mTorr in an oxygen atmosphere at a growth rate of 16 A/minute. Subsequently, a gold thin film having a thickness of 50 A was formed as the upper electrode (the first electrode) 7, and then a heat treatment was conducted at 450° C. and 1 atm in an oxygen atmosphere. An auxiliary electrode 11 (200A) was formed on the lower substrate 5 by using titanium metal. FIG. 7 shows photo-current-voltage characteristics observed when the solar cell 1 using the Mott insulator was irradiated with standard light having the same wavelength intensity as that of sunlight. It can be seen from FIG. 7 that a photoelectromotive force is generated even when a Mott insulator is used as the solid material forming the p-n junction.

Note that the p-n junction structure containing a Mott insulator or a Mott semiconductor has been described as a solar cell in the present invention, but can also be applied to photo detectors (photo diodes).

1. A solar cell comprising
a junction structure between a first solid material layer and a second solid material layer, the first solid material layer comprising a p- or n-type insulator or a p- or n-type semiconductor, the second solid material layer comprising a different type of an insulator or semiconductor from the type of the first solid material layer, wherein
a solid material of at least one layer of the first solid material layer and the second solid material layer is a Mott insulator or a Mott semiconductor.

2. The solar cell according to claim 1, wherein
the first solid material layer is provided on the second solid material layer, and
a first electrode is provided on a sunlight-receiving surface on the first solid material layer.

3. The solar cell according to claim 1, further comprising
a second electrode provided on a side of the second solid material layer, the side being opposite to a side on which the second solid material layer is in contact with the first solid material layer.

4. The solar cell according to claim 1, wherein
two or more of the p-n junction structures each formed of the first solid material layer and the second solid material layer are provided, and
the p-n junction structures are connected in series.

5. The solar cell according to claim 1, wherein
a light-receiving surface of the solar cell has an irregular surface structure.

6. The solar cell according to claim 1, wherein
the Mott insulator or the Mott semiconductor contains one or more transition metal elements selected from the group consisting of titanium, vanadium, chromium, manganese, iron, cobalt, nickel, copper, zinc, niobium, molybdenum, ruthenium, rhodium, cadmium, indium, tin, tantalum, tungsten, rhenium, osmium, iridium, and platinum.

7. The solar cell according to claim 1, wherein
the Mott insulator or the Mott semiconductor is an inorganic compound represented by any one of the following general formulae (1) to (8):
LnₓA₁₋ₓBO₃ (1)
LnAB₂O₆ (2)
Ln₁₋ₓA₁₊ₓBO₄ (3)
Ln₂₋₂ₓA₁₊₂ₓB₂O₇ (4)
Ln₂₋ₓAₓBO₄ (5)
A₂BO₃ (6)
A₂BO₄ (7)
A₂BO₂Cl₂ (8)
(where Ln represents one or more rare-earth elements selected from the group consisting of lanthanum, cerium, praseodymium, neodymium, samarium, europium, gadolinium, terbium, dysprosium, holmium, erbium, thulium, ytterbium, and lutetium; A represents one or more alkaline earth metal elements selected from the group consisting of beryllium, magnesium, calcium, strontium, and barium; B represents one or more transition metal elements selected from the group consisting of titanium, vanadium, chromium, manganese, iron, cobalt, nickel, copper, zinc, niobium, molybdenum, ruthenium, rhodium, cadmium, indium, tin, tantalum, tungsten, rhenium, osmium, iridium, and platinum; O represents oxygen element, Cl represents chlorine element; and x satisfies 0≦x≦1).

8. The solar cell according to claim 1, wherein
the Mott insulator or the Mott semiconductor is any one of vanadium oxide, niobium oxide, tantalum oxide, chromium oxide, molybdenum oxide, tungsten oxide, and rhenium oxide.

9. The solar cell according to claim 1, wherein
the Mott insulator or the Mott semiconductor is one or more organic compounds selected from the group consisting of aromatic amine compounds, carbazole derivatives, aromatic hydrocarbons, polymer compounds, and charge transfer complexes.

10. The solar cell according to claim 9, wherein
the charge transfer complex is any one of a quasi-one-dimensional halogen-bridged metal complex [MX complex] where a transition metal (M) and a halogen (X) are alternately arranged, a quasi-one-dimensional halogen-bridged multinuclear metal complex [MMX complex], and a quasi-one-dimensional charge transfer complex including tetrathiafulvalene [TTF] and chloranil [CA].
